(19) United States
(12) Patent Application Publication
(10) Pub. No.: US 2026/0350275 A1
(43) Pub. Date: Nov. 5, 2026

(54) MODIFYING WELLBORE LOGS WITH POOR DATA QUALITY

(71) Applicant: Schlumberger Technology Corporation, Sugar Land, TX (US)

(72) Inventors: Vanessa da Silva Simoes, Houston, TX (US); Hiren Maniar, Houston, TX (US)

(21) Appl. No.: 19/637,775

(22) Filed: Apr. 2, 2026

Related U.S. Application Data
(60) Provisional application No. 63/798,721, filed on May 2, 2025.

(51) Int. Cl. G06F 30/28; G06F 16/215

(52) U.S. Cl. CPC G06F 30/28; G06F 16/215

(57) ABSTRACT

A method for modifying well log data with poor quality includes receiving input data. The method also includes identifying low-quality intervals in the input data having a quality that is below a quality threshold. Identifying the low-quality intervals includes determining a borehole rugosity based upon a first subset of the input data. The method also includes fine-tuning a pre-trained model based upon the low-quality intervals to produce a fine-tuned model.

### CROSS-REFERENCE TO RELATED APPLICATIONS

This application claims priority to U.S. Provisional Patent Application No. 63/798,721, filed on 2 May. 2025, which is incorporated by reference.

### BACKGROUND

A downhole logging tool may capture measurements that are used to generate one or more wellbore logs. However, sometimes, these wellbore logs may have poor data quality. This poor quality may be due to the diversity of the subsurface, the high costs associated with obtaining training label data, input wellbore logs with low quality intervals and inconsistent data, and one or more missing log types in each interval. Therefore, what is needed is an improved system and method for modifying (e.g., correcting) wellbore logs with poor data quality.

### SUMMARY

A method for modifying well log data with poor quality is disclosed. The method includes receiving input data. The method also includes identifying low-quality intervals in the input data having a quality that is below a quality threshold. Identifying the low-quality intervals includes determining a borehole rugosity based upon a first subset of the input data. The method also includes fine-tuning a pre-trained model based upon the low-quality intervals to produce a fine-tuned model.

A computing system is also disclosed. The computing system includes one or more processors and a memory system. The memory system includes one or more non-transitory computer-readable media storing instructions that, when executed by at least one of the one or more processors, cause the computing system to perform operations. The operations include receiving first input data. The first input data includes first well log data. A first subset of the first well log data includes caliper data. A second subset of the first well log data does not include the caliper data. The operations also include fine-tuning a first pre-trained model based upon the first input data to produce a first fine-tuned model. The operations also include identifying first low-quality intervals in the first input data having a quality that is below a quality threshold. The first low-quality intervals are identified using the first fine-tuned model. Identifying the first low-quality intervals includes determining a borehole rugosity based upon the first subset of the first input data. The borehole rugosity is determined based upon the caliper data. Identifying the first low-quality intervals also includes creating washout flags in the first subset of the first input data based upon the borehole rugosity. The operations also include fine-tuning a second pre-trained model based upon the first low-quality intervals to produce a second fine-tuned model. The second pre-trained model is fine-tuned based upon the washout flags. The second pre-trained model is fine-tuned to predict the washout flags in the second subset of the first input data that does not include the caliper data.

A non-transitory computer-readable medium is also disclosed. The medium includes instructions that, when executed by one or more processors of a computing system, cause the computing system to perform operations. The operations include receiving first input data. The first input data includes first well log data. The first well log data includes measured data and metadata. The measured data is captured by a downhole tool in a borehole. The measured data includes a photo electric factor, caliper data, resistivity data, acoustic data, neutron data, density data, or a combination thereof. A first subset of the first well log data includes the caliper data. A second subset of the first well log data does not include the caliper data. The operations also include identifying cased intervals and open hole intervals in the first input data. The cased intervals and the open hole intervals are identified based upon (1) the metadata (2) the photo electric factor being above a factor threshold, (3) the neutron data being influenced by mud behind a casing, (4) the resistivity data presenting anomalous values, and/or (5) the acoustic data being influenced by a wave propagating on the casing. The operations also include fine-tuning a first pre-trained model based upon the first input data to produce a first fine-tuned model. The first pre-trained model is fine-tuned based upon the cased intervals and the open hole intervals. The first pre-trained model is fine-tuned to classify the borehole in a database. The first pre-trained model is a deep learning model. The operations also include identifying first low-quality intervals in the first input data having a quality that is below a quality threshold. The first low-quality intervals are identified in the open hole intervals. The first low-quality intervals are identified using the first fine-tuned model. The quality is below the quality threshold due to a washout in the borehole and/or missing data. Identifying the first low-quality intervals includes determining a borehole rugosity based upon the first subset of the first input data. The borehole rugosity is determined based upon the caliper data. Identifying the first low-quality intervals also includes creating washout flags in the first subset of the first input data based upon the borehole rugosity. Identifying the first low-quality intervals also includes predicting coal intervals in the first subset of the first input data that include coal. The coal intervals are predicted using the first pre-trained model. Identifying the first low-quality intervals also includes deactivating a subset of the washout flags that are aligned with the coal intervals. The operations also include fine-tuning a second pre-trained model based upon the first low-quality intervals to produce a second fine-tuned model. The second pre-trained model is fine-tuned based upon the washout flags. The second pre-trained model is fine-tuned to predict the washout flags in the second subset of the first input data that does not include the caliper data. The operations also include removing the first low-quality intervals from the first input data using the second fine-tuned model to produce filtered data. The first low-quality intervals are removed from the first subset of the first input data. The operations also include fine-tuning a third pre-trained model based upon the filtered data to produce a third fine-tuned model. The first, second, and/or third pre-trained models are the same pre-trained models or different pre-trained models. The third fine-tuned model is a denoising model. The third pre-trained trained model is fine-tuned using denoising multitask paradigms that accounts for missing intervals, depth shifts, intensity shifts, random noises from different distributions, correlated noises, and/or corruption of frequency components.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a system that includes various management components to manage various aspects of a geologic environment, according to an embodiment.

FIG. 2 illustrates a flowchart of a method for modifying (e.g., correcting) well log data with poor quality (e.g., below a quality threshold), according to an embodiment.

FIG. 3 illustrates a flowchart of another method for modifying (e.g., correcting) well log data with poor quality, according to an embodiment.

FIG. 4 illustrates first input data (e.g., measured well log data) including a photo electric factor (PEF), caliper data (CALI), resistivity data for deep (RES_DP), resistivity data for shallow (RES_SH), acoustic data (DTC), neutron data (NEUT), density data (RHOB), according to an embodiment.

FIG. 5 illustrates the first input data (e.g., measured well log data) identifying cased intervals and open hole intervals, according to an embodiment.

FIG. 6 illustrates the first input data (e.g., measured well log data) showing intervals affected by the casing, according to an embodiment.

FIG. 7 illustrates low-quality intervals in the acoustic slowness (DTC), according to an embodiment.

FIG. 8 illustrates washout flags in the borehole rugosity column of the first input data, according to an embodiment.

FIG. 9 illustrates an output image showing the original logs (e.g., first input data), the conditioned data, and the flags, according to an embodiment.

FIGS. 10A and 10B illustrate graphs showing the original data and the conditioned data, according to an embodiment.

FIG. 11 illustrates a schematic view of a computing system for performing at least a portion of the method(s) described herein, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

### System Overview

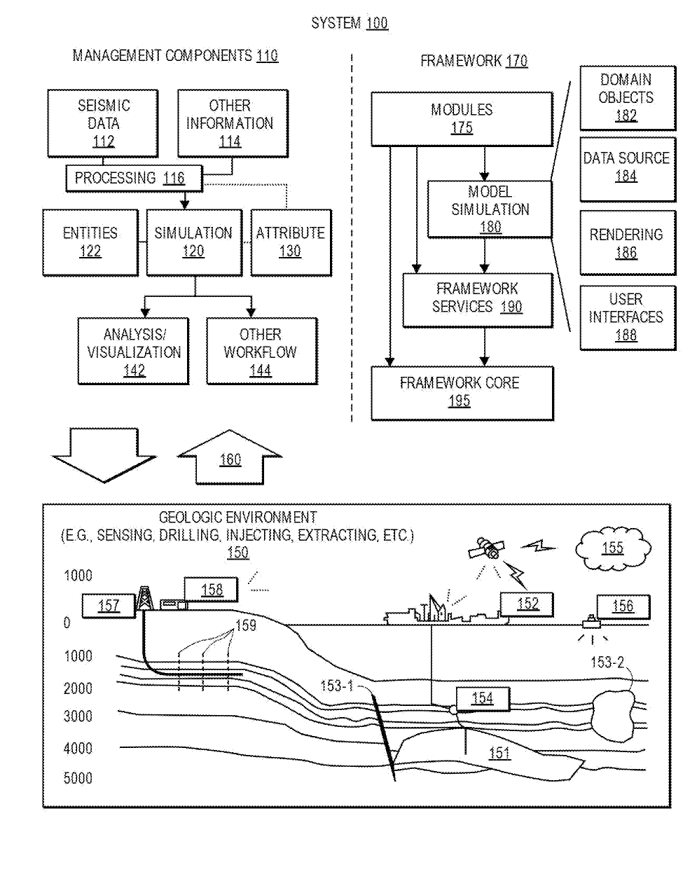

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example embodiment, the simulation component 120 may rely on entities 122. Entities 122 may include earth entities or geological objects such as wells, surfaces, bodies, reservoirs, etc. In the system 100, the entities 122 can include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. A commercially available example of an object-based framework is the MICROSOFT^{®} .NET^{®} framework (Redmond, Washington), which provides a set of extensible object classes. In the .NET^{®} framework, an object class encapsulates a module of reusable code and associated data structures. Object classes can be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE^{TM} reservoir simulator (SLB, Houston Texas), the INTERSECT^{TM} reservoir simulator (SLB, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

As an example, the simulation component 120 may include one or more features of a simulator such as SYMMETRY software (SLB, Houston, Texas). More particularly, SYMMETRY may process workflows in a single integrated environment with accurate thermodynamic fluid representation and consistent modeling across multiple disciplines including process, production, and HSE. The simulator integrates steady-state and transient (e.g., dynamic) analyses that can be tailored for each domain. This approach enables users to optimize processes in upstream, midstream, and downstream sectors while maximizing profits and minimizing capital expenditures. It may also help reduce emissions, energy consumption, and waste.

As an example, the simulation component 120 may include one or more features of a simulator such as PIPESIM (SLB, Houston, Texas). More particularly, PIPESIM is steady-state multiphase flow simulator that incorporates the three areas of flow modeling: multiphase flow, heat transfer and fluid behavior.

As an example, the simulation component 120 may include one or more features of a simulator such as OLGA™ (SLB, Houston, Texas). More particularly, OLGA™ is a dynamic multiphase flow simulator that models transient flow (e.g., time-dependent behaviors) to maximize production potential. Transient modeling is a component for feasibility studies and field development design. Dynamic simulation is useful in deep water and is used in both offshore and onshore developments to investigate transient behavior in pipelines and wellbores. Transient simulation with the OLGA™ simulator provides an added dimension to steady-state analysis by predicting system dynamics, such as time-varying changes in flow rates, fluid compositions, temperature, solids deposition, and operational changes.

In an example embodiment, the management components 110 may include features of a commercially available framework such as the PETREL^{®} seismic to simulation software framework (SLB, Houston, Texas). The PETREL^{®} framework provides components that allow for optimization of exploration and development operations. The PETREL^{®} framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes. Such a framework may be considered an application and may be considered a data-driven application (e.g., where data is input for purposes of modeling, simulating, etc.).

In an example embodiment, various aspects of the management components 110 may include add-ons or plug-ins that operate according to specifications of a framework environment. For example, a commercially available framework environment marketed as the OCEAN^{®} framework environment (SLB, Houston, Texas) allows for integration of add-ons (or plug-ins) into a PETREL^{®} framework workflow. The OCEAN^{®} framework environment leverages .NET^{®} tools (Microsoft Corporation, Redmond, Washington) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN^{®} framework where the model simulation layer 180 is the commercially available PETREL^{®} model-centric software package that hosts OCEAN^{®} framework applications. In an example embodiment, the PETREL^{®} software may be considered a data-driven application. The PETREL^{®} software can include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components.

As an example, the domain objects 182 can include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project can be accessed and restored using the model simulation layer 180, which can recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL^{®} software, for example, that operates on seismic data, seismic attribute(s), etc. As an example, a workflow may be a process implementable in the OCEAN^{®} framework. As an example, a workflow may include one or more worksteps that access a module such as a plug-in (e.g., external executable code, etc.).

### Modifying Wellbore Logs in Sessions with Poor Data Quality

The method described herein may be used to modify (e.g., correct) wellbore logs in bad hole sessions. The method uses deep learning methods for knowledge extraction and to increase the range of the workflow applicability. A portion of the method may involve optional user interaction. The method may also define some hyperparameters that can be optionally tuned by users and, when the user accepts the terms, can be collected as a metadata to improve automation and accuracy for the next versions of the workflow.

A deep learning model used in field tests may be based on window base pre-trained models for general using self-supervised techniques and the concept of foundational models. This self-supervised approach allows for the model to handle one or more missing input logs during training or inference. The window-based approach allows for the method to learn from nearby depths and provides a more continuous prediction.

As part of a larger initiative to build domain workflows that augment the domain experts via pre-trained models (e.g., using the idea of foundational models), reinforcement learning, expert interaction, and agent orchestration, the method may modify (e.g., correct) well logs with poor quality (e.g., below a quality threshold) considering the caliper information, the joint distribution of the multiple available input logs, and/or the user feedback.

As mentioned above, portions of the method may be optional, where the user can interact and realign the workflow results in a few intervals and wells, and the method propagates those aligned results for the entire field which can contain thousands of wells. The information from expert feedback contributes to the workflow in three forms: (1) determination of hyper parameters, (2) providing examples used to fine-tune the deep learning pre-trained models or machine learning model if a pre-trained model is not to be used, and (3) depending on the contract agreement and data license, the feedback or meta data may be used for future realignment of the method. The method includes data, instruction, and user information to perform the tasks, and the method allows for loops (i.e., iterations) to align the results until success.

### Exemplary Method

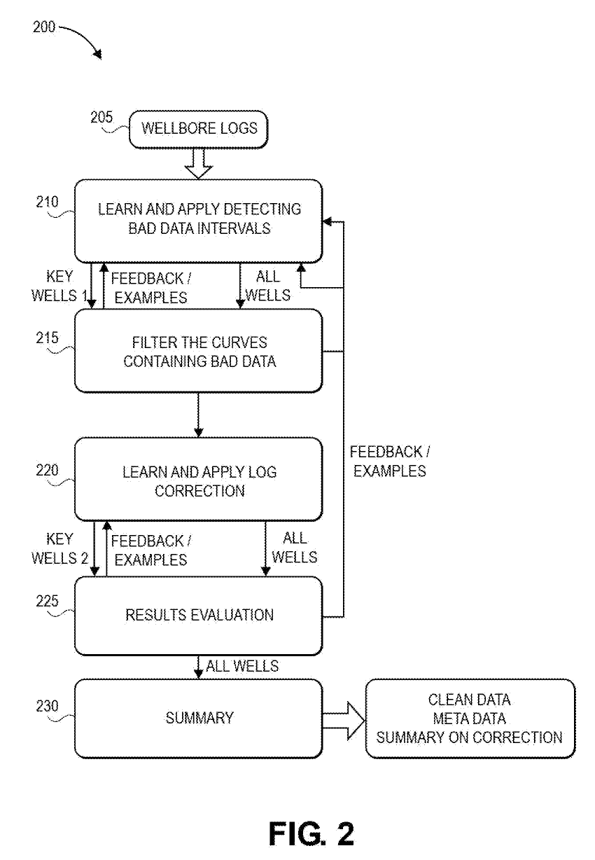

FIG. 2 illustrates a flowchart of a method 200 for modifying (e.g., correcting) well log data with poor quality (e.g., below a quality threshold), according to an embodiment. An illustrative order of the method 200 is provided below; however, one or more portions of the method 200 may be performed in a different order, simultaneously, repeated, or omitted. At least a portion of the method 200 may be performed using a computing system.

The method 200 may include receiving input data, as at 205. The input data may be or include well log data (e.g., acquired by a downhole tool in a wellbore).

The method 200 may also include learning and applying to detect bad data intervals, as at 210. In an example, this may include detecting in-casing intervals for wells using the well metadata combined with measurement indications in casing intervals, such as high photo electric factor. The open hole intervals may be the well minus the in-casing intervals. The in-casing and open hole intervals may be used to fine tune a pre-trained deep learning model to learn to classify the intervals. The fine-tuned model may then be used to propagate this classification to multiple wells in the database. The following may be restricted to the open hole portions of the wells.

Where there is caliper calculate the borehole rugosity based on the caliper, a flag may be activated when this quantity is larger than a cut off value. The flag may be used as a first washout flag. The coal intervals may be predicted using a pre-trained model. A subset of the intervals covering multiple formation types may be selected for presenting the washout flag and coal flag results. In an example, the results can be presented as a log view for certain intervals and as a cross plot (e.g., cross plots of neutron and density color coded by flag). In another example, in response to first user feedback, one or more options of the curve may be calculated with different cut off values. The user may then select one (e.g., best) curve. In another example, in response to second user feedback, the use may edit of the intervals from the best cut-off values.

The washout flag may be used by subtracting zones with coal from wells (e.g., optionally improved with user feedback), as a combined bad data flag to fine tune a pre-trained model (or train a machine learning model) using the available log measurements and having the bad data flag as a target. The model predicts the bad (e.g., low quality) data intervals based on multiple measurements on caliper. This may also work for wells without the caliper measurement or some other missing logs.

The method 200 may also include filtering the curves and intervals affected by bad data signal, as at 215. More particularly, the bad hole flag may be used to filter out the values from the selected curves of interest (e.g., density and/or neutron porosity).

The method 200 may also include learning and applying a log correction, as at 220. This may include training a deep learning model with inputs given by multiple curved derived from the measured logs (e.g., normalized logs or transformed logs). Outputs of the deep learning model may be given by the targets of interest to be predicted, which may be already filtered from the bad hole flags using the steps above. Additional logs can also be part of the outputs (e.g., DTC, PEF). The model may be applied in wells or intervals.

The method 200 may also include evaluating results, as at 225. The results may be presented in a subset of intervals (e.g., via a depth plot format and/or a cross plot format). The cross plot format may include cross plots of neutron versus density. They may be color coded by washout before and after log correction. The log depth plot may contain the original curves, the corrected/predicted curves, and/or a third curve containing a joined curve where the values are a combination of the original curve (e.g., where the logs are available) and the corrected/predicted curve. User feedback may be determined from the results and then used to regenerate the flags and corrections by changing some hyper parameters in the model final tuning.

The method 200 may also include generating a summary, as at 230. The input logs and the corrected logs may be used to calculate metrics, summarize the workflow findings, and organize this into a desired format for the user and ready to answer questions.

### Exemplary Method

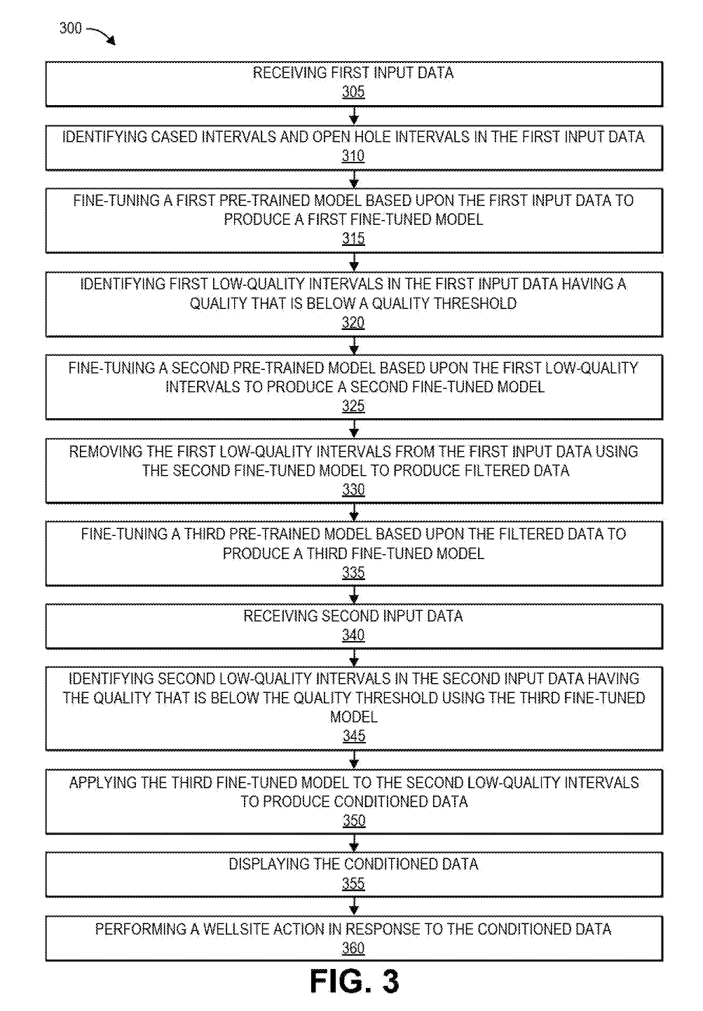

FIG. 3 illustrates a flowchart of another method 300 for modifying (e.g., correcting) well log data with poor quality, according to an embodiment. An illustrative order of the method 300 is provided below; however, one or more portions of the method 300 may be performed in a different order, simultaneously, repeated, or omitted. At least a portion of the method 300 may be performed using a computing system.

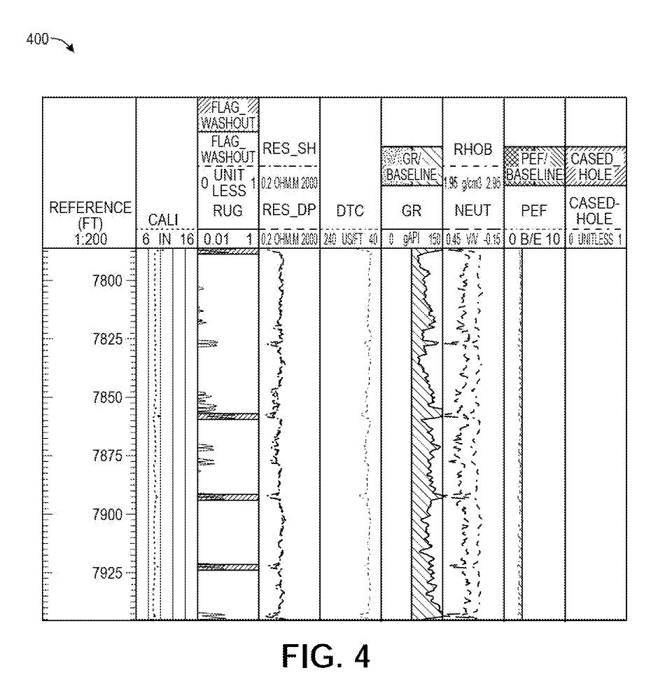

The method 300 may include receiving first input data, as at 305. This may be similar to or part of 205 in FIG. 2. The first input data may include first well log data. The first well log data may include measured data and/or metadata. The measured data may be captured by a downhole tool in a borehole. FIG. 4 illustrates first input data (e.g., measured well log data) 400 including a photo electric factor (PEF), caliper data (CALI), resistivity data for deep (RES_DP), resistivity data for shallow (RES_SH), acoustic data (DTC), neutron data (NEUT), density data (RHOB), according to an embodiment. In an example, a first subset of the first well log data may include the caliper data, and a second subset of the first well log data may not include the caliper data.

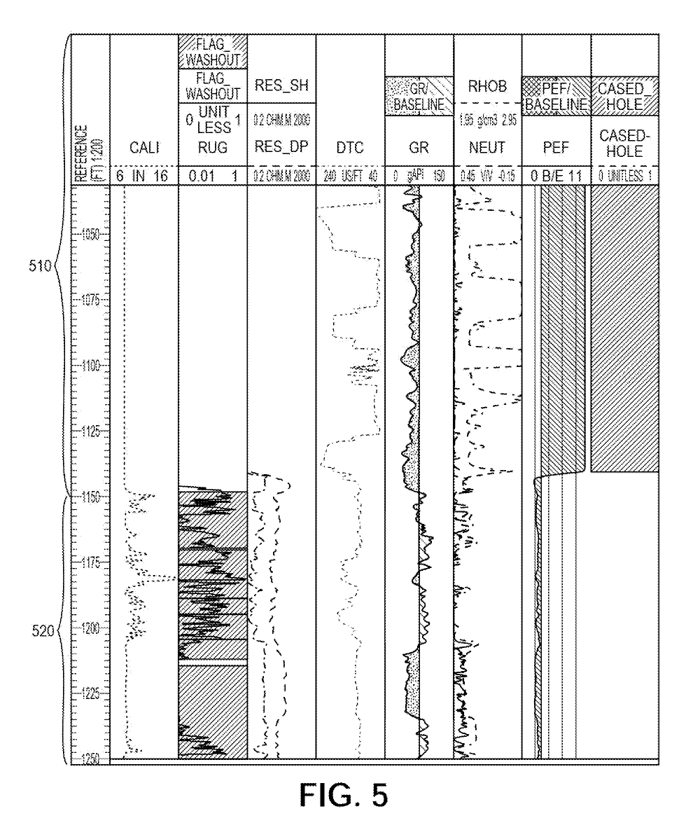

The method 300 may also include identifying cased intervals and open hole intervals in the first input data, as at 310. FIG. 5 illustrates the first input data (e.g., measured well log data) 400 identifying cased intervals 510 and open hole intervals 520, according to an embodiment. The cased intervals and the open hole intervals may be identified based upon (1) the metadata (2) the photo electric factor being above a factor threshold, (3) the neutron data being influenced by mud behind a casing, (4) the resistivity data presenting anomalous values, (5) the acoustic data being influenced by a wave propagating on the casing, or a combination thereof.

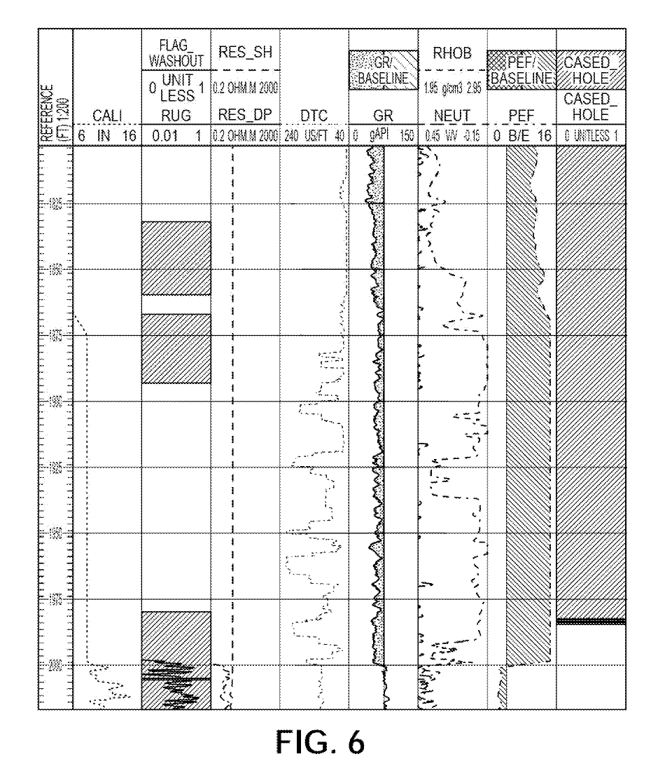

FIG. 6 illustrates the first input data (e.g., measured well log data) showing intervals affected by the casing, according to an embodiment. In this example, the DTC shows the casing arrival (57 us/ft). The GR reading is lower than the formation GR showing attenuation due to the casing. The PEF measurement is higher than the formation PEF. In other words, the shallow measurement reads high due to the atomic number of iron in the casing. The neutron reading is high and affected by cement or fluid behind the casing.

The method 300 may also include fine-tuning a first pre-trained model based upon the first input data to produce a first fine-tuned model, as at 315. The first pre-trained model may be fine-tuned based upon the cased intervals and/or the open hole intervals. The first pre-trained model may be fine-tuned to classify the borehole in a database. The first pre-trained model may be a deep learning model.

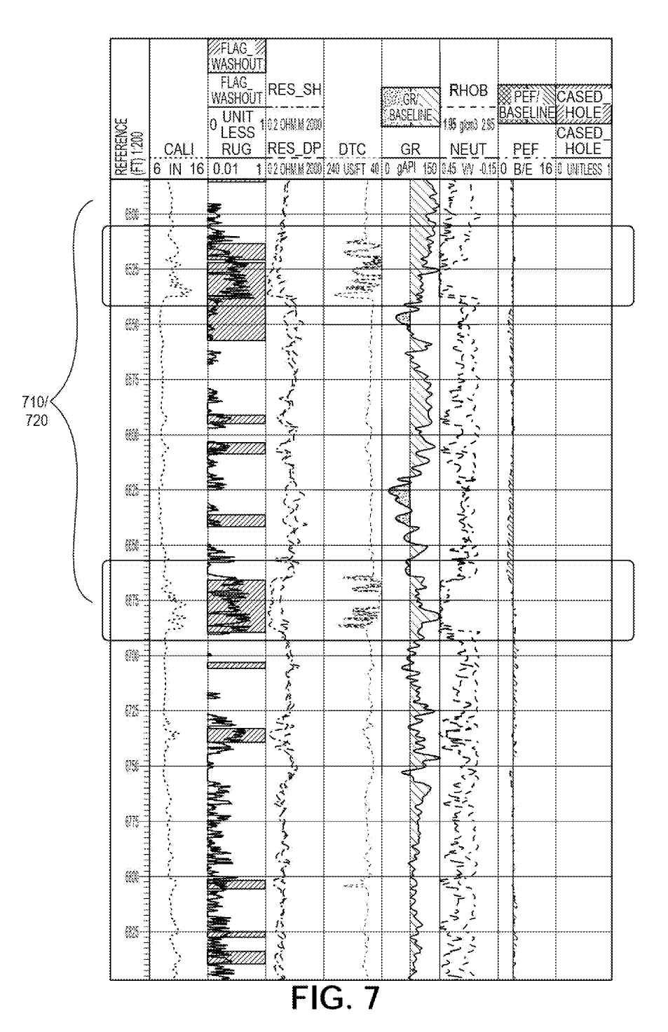

The method 300 may also include identifying first low-quality intervals in the first input data having a quality that is below a quality threshold, as at 320. This may be similar to or part of 210 in FIG. 2. FIG. 7 illustrates low-quality intervals 710, 720 in the acoustic slowness (DTC), according to an embodiment. The first low-quality intervals may be identified in the open hole intervals. The first low-quality intervals may be identified using the first fine-tuned model. In an example, the quality may be below the quality threshold due to a washout in the borehole and/or missing data.

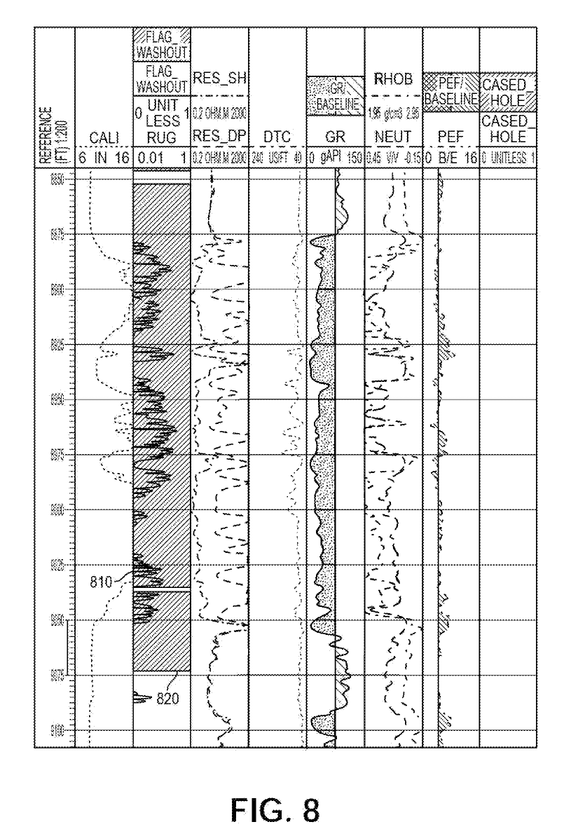

In an embodiment, identifying the first low-quality intervals may include determining a borehole rugosity based upon the first subset of the first input data. The borehole rugosity may be determined based upon the caliper data. Identifying the first low-quality intervals may also include creating washout flags in the first subset of the first input data based upon the borehole rugosity. FIG. 8 illustrates washout flags 810, 820 in the borehole rugosity column of the first input data, according to an embodiment. Identifying the first low-quality intervals may also include predicting coal intervals in the first subset of the first input data that include coal. The coal intervals may be predicted using a pre-trained model. Identifying the first low-quality intervals may also include deactivating a subset of the washout flags that are aligned with the coal intervals.

The method 300 may also include fine-tuning a second pre-trained model based upon the first low-quality intervals to produce a second fine-tuned model, as at 325. The second pre-trained model may be fine-tuned based upon the washout flags. In an example, the second pre-trained model may be fine-tuned to predict the washout flags in the second subset of the first input data that does not include the caliper data.

The method 300 may also include removing the first low-quality intervals from the first input data using the second fine-tuned model to produce filtered data, as at 330. This may be similar to or part of 215 in FIG. 2. The first low-quality intervals may be removed from the first subset of the first input data.

The method 300 may also include fine-tuning a third pre-trained model based upon the filtered data to produce a third fine-tuned model, as at 335. This may be similar to or part of 220 in FIG. 2. The first, second, and/or third pre-trained models may be the same pre-trained models or different pre-trained models. The third fine-tuned model may be a denoising model. The third pre-trained trained model may be fine-tuned using denoising multitask paradigms that accounts for missing intervals, depth shifts, intensity shifts, random noises from different distributions, correlated noises, and/or corruption of frequency components.

The method 300 may also include receiving second input data, as at 340. The second input data may include second well log data.

The method 300 may also include identifying second low-quality intervals in the second input data having the quality that is below the quality threshold, as at 345. The second low-quality intervals may be identified using the third fine-tuned model.

The method 300 may also include applying the third fine-tuned model to the second low-quality intervals to produce conditioned data, as at 350. This may be similar to or part of 220 in FIG. 2. This may improve a completeness and/or a consistency of the second input data.

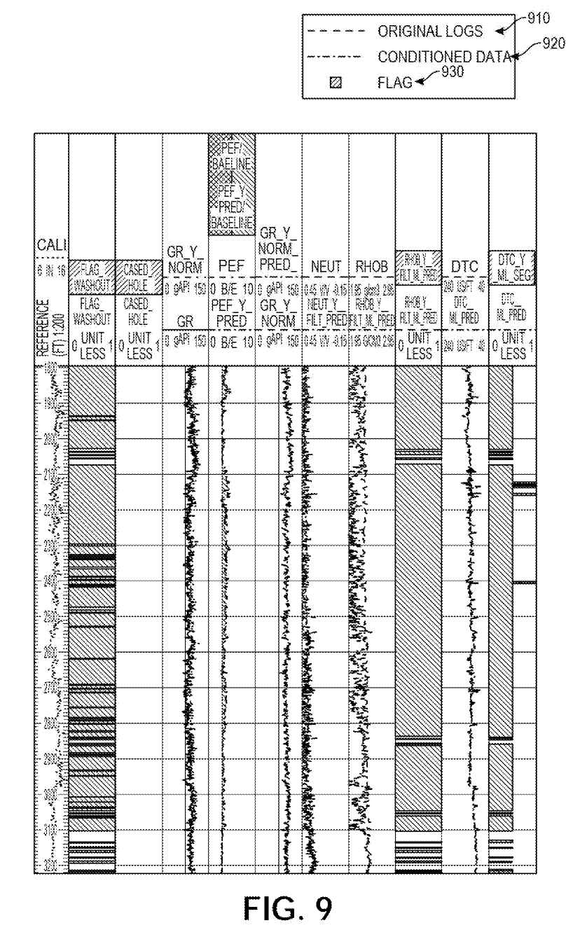

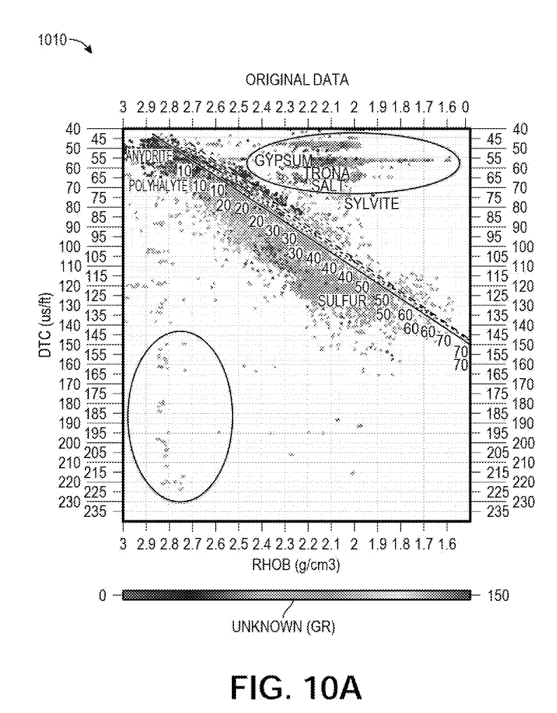

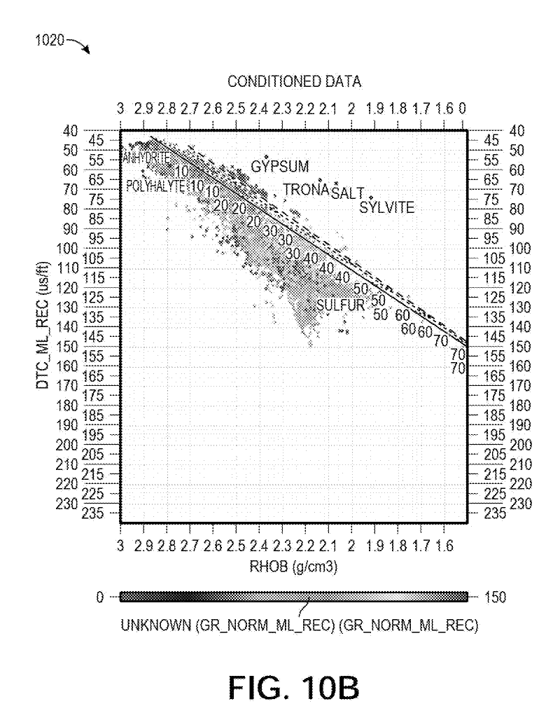

The method 300 may also include displaying the conditioned data, as at 355. This may be similar to or part of 230 in FIG. 2. The conditioned data may be displayed nearby the second input data and the washout flags. FIG. 9 illustrates an output image showing the original logs (e.g., first input data) 910, the conditioned data 920, and the flags 930, according to an embodiment. FIGS. 10A and 10B illustrate graphs showing the original data 1010 and the conditioned data 1020, according to an embodiment.

The method 300 may also include performing a wellsite action based upon and/or in response to the conditioned data, as at 360. The wellsite action may include generating and/or transmitting a signal that recommends, instructs, or causes a physical action to occur. The wellsite action may also or instead include performing the physical action. The physical action may include modifying the quality threshold, re-fine-tuning the third fine-tuned model, further modifying the conditioned data. In another embodiment, the physical action may include selecting where to drill a wellbore, drilling the wellbore, varying a weight and/or torque on a drill bit that is drilling the wellbore, varying a drilling trajectory of the wellbore, varying a concentration and/or flow rate of a fluid pumped into the wellbore, or the like.

For example, in response to the conditioned data showing lower porosity than a predetermined threshold, the physical action may be or include (a) reevaluating the oil reserves for a specific layer that had been misinterpreted due to washout effects, or (b) reevaluating the geomechanical 1D properties when detecting an interval of compressional travel time (DTC) with poor quality measurements. The predetermined threshold may be what a neutron log first indicated. Revaluating the oil reserves may include varying a drilling trajectory to aim toward the specific layer in response to the specific layer now showing a higher likelihood or amount of oil after reevaluation/reinterpretation. Conversely, revaluating the oil reserves may include varying a drilling trajectory to aim away from the specific layer in response to the specific layer now showing a lower likelihood or amount of oil and/or higher likelihood of washout effects after reevaluation/reinterpretation.

The methods 200, 300 may be fully automated and may consider user input. They may also be used when some of the input logs are missing. In contrast, conventional methods may use a bad hole flag that doesn’t work when the caliper is not available. Conventional methods may also fail to consider the sequential data to improve corrected log continuity. Conventional methods also lack user feedback, which prevents the model from improving from the examples in real time, from metadata, or from shared examples with proper consent to allow for continuous improvement.

The methods 200, 300 consider the intercorrelation between the well logs, and they can be used in intervals where some of the information is missing (e.g., caliper, density, or neutron). The methods 200, 300 also consider the sequential correlation providing corrected curves with bigger continuity and considering the nearby available intervals.

Further, the methods 200, 300 address the challenge of incorporating expert feedback into the model. This incorporation may be performed in the following levels of information extraction. Level 1 may be performed when learning in real time from the few examples from intervals to be used to fine-tune the deep learning models to provide the answer more aligned with user standards. Level 2 may be performed when the meta information is shared by the user. The meta data may be used to understand the direction and/or to improve the model. This may control precision versus accuracy for the user, or influence other log types or additional information in the user edited curve. Level 3 may be used in cases where the data and the user agreement allow. A third source of information may be or include the labels provided by the user. This may be information that can be used to improve and validate the workflow.

In an embodiment, a first application of the methods 200, 300 may include performing log quality control of a large dataset with hundreds or thousands of wells, where automation is used to augment the expert. In this scenario, the methods 200, 300 may provide corrected logs: (1) considering the knowledge from the expert on certain wells via the user interaction process, (2) considering a combination of multiple log types as input in many wells in the basin via the usage of deep learning models, and/or (3) in a fraction of the time compared to manual processing. In another embodiment, a second application of the methods 200, 300 may include automating data cleaning when performing additional downstream applications, where the bad quality zones can damage the overall interpretation.

The methods 200, 300 may use deep learning implicitly considering the joint distribution of the multiple log types available for each depth. The methods 200, 300 may also process wells or intervals where caliper or other logs are missing. The methods 200, 300 may also provide expert augmentation via user interaction to calibrate the model parameters or work steps and improve the fine-tuning stage of the deep learning models via examples with improved user acceptance. The methods 200, 300 may leverage the power of AI for expert augmentation to derive results that are aligned with the expert accepted criteriums. The collection of meta data or labels can be a good starting point for defining the rules, pricing, and agreements.

### Exemplary Computing System

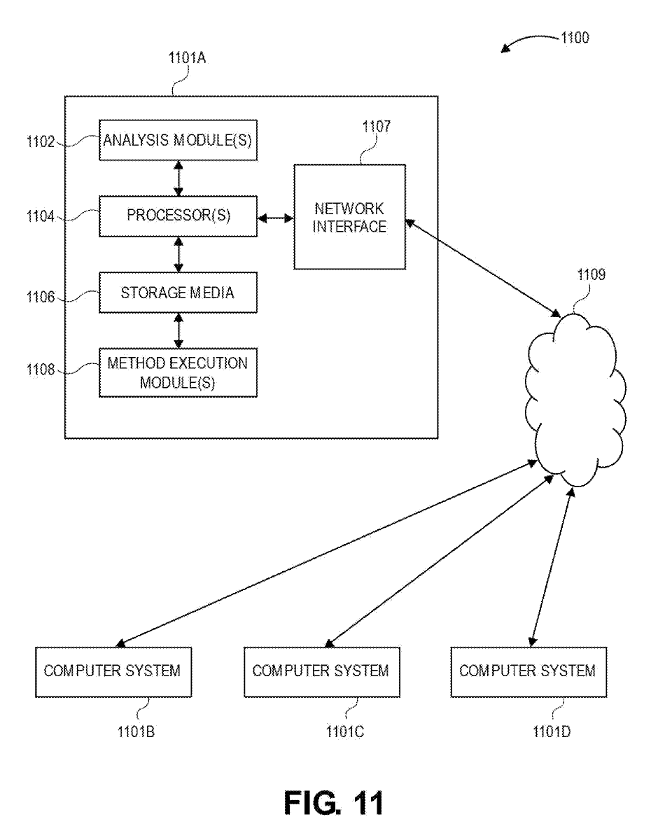

In some embodiments, the methods of the present disclosure may be executed by a computing system. FIG. 11 illustrates an example of such a computing system 1100, in accordance with some embodiments. The computing system 1100 may include a computer or computer system 1101A, which may be an individual computer system 1101A or an arrangement of distributed computer systems. The computer system 1101A includes one or more analysis modules 1102 that are configured to perform various tasks according to some embodiments, such as one or more methods disclosed herein. To perform these various tasks, the analysis module 1102 executes independently, or in coordination with, one or more processors 1104, which is (or are) connected to one or more storage media 1106. The processor(s) 1104 is (or are) also connected to a network interface 1107 to allow the computer system 1101A to communicate over a data network 1109 with one or more additional computer systems and/or computing systems, such as 1101B, 1101C, and/or 1101D (note that computer systems 1101B, 1101C and/or 1101D may or may not share the same architecture as computer system 1101A, and may be located in different physical locations, e.g., computer systems 1101A and 1101B may be located in a processing facility, while in communication with one or more computer systems such as 1101C and/or 1101D that are located in one or more data centers, and/or located in varying countries on different continents).

A processor may include a microprocessor, microcontroller, processor module or subsystem, programmable integrated circuit, programmable gate array, or another control or computing device.

The storage media 1106 may be implemented as one or more computer-readable or machine-readable storage media. Note that while in the example embodiment of FIG. 11 storage media 1106 is depicted as within computer system 1101A, in some embodiments, storage media 1106 may be distributed within and/or across multiple internal and/or external enclosures of computing system 1101A and/or additional computing systems. Storage media 1106 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY^{®} disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 1100 contains one or more method execution module(s) 1108. In the example of computing system 1100, computer system 1101A includes the method execution module 1108. In some embodiments, a single method execution module may be used to perform some aspects of one or more embodiments of the methods disclosed herein. In other embodiments, a plurality of method execution modules may be used to perform some aspects of methods herein.

It should be appreciated that computing system 1100 is merely one example of a computing system, and that computing system 1100 may have more or fewer components than shown, may combine additional components not depicted in the example embodiment of FIG. 11, and/or computing system 1100 may have a different configuration or arrangement of the components depicted in FIG. 11. The various components shown in FIG. 11 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 1100, FIG. 11), and/or through manual control by a user who may make determinations regarding whether a given step, action, template, model, or set of curves has become sufficiently accurate for the evaluation of the subsurface three-dimensional geologic formation under consideration.

The foregoing description, for purposes of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrated and described may be re-arranged, and/or two or more elements may occur simultaneously. The embodiments were chosen and described in order to best explain the principles of the disclosure and its practical applications, to thereby enable others skilled in the art to best utilize the disclosed embodiments and various embodiments with various modifications as are suited to the particular use contemplated.

What is claimed is:

1. A method for modifying well log data with poor quality, the method comprising:
receiving input data;
identifying low-quality intervals in the input data having a quality that is below a quality threshold, wherein identifying the low-quality intervals comprises determining a borehole rugosity based upon a first subset of the input data; and
fine-tuning a pre-trained model based upon the low-quality intervals to produce a fine-tuned model.

2. The method of claim 1, wherein the input data comprises well log data that is captured by a downhole tool in a borehole.

3. The method of claim 2, wherein the quality is below the quality threshold due to a washout in the borehole.

4. The method of claim 1, wherein the first subset of the input data comprises caliper data, and wherein the borehole rugosity is determined based upon the caliper data.

5. The method of claim 4, wherein identifying the low-quality intervals further comprises creating washout flags in the first subset of the input data based upon the borehole rugosity, and wherein the pre-trained model is fine-tuned based upon the washout flags.

6. The method of claim 5, wherein a second subset of the input data does not include the caliper data, and wherein the pre-trained model is fine-tuned to predict the washout flags in the second subset of the input data.

7. The method of claim 5, wherein identifying the low-quality intervals further comprises predicting coal intervals in the first subset of the input data.

8. The method of claim 7, wherein identifying the low-quality intervals further comprises deactivating a subset of the washout flags that are aligned with the coal intervals.

9. The method of claim 1, further comprising displaying an output of the pre-trained model.

10. The method of claim 1, further comprising performing a physical action in response to an output of the pre-trained model.

11. A computing system, comprising:
one or more processors; and
a memory system comprising one or more non-transitory computer-readable media storing instructions that, when executed by at least one of the one or more processors, cause the computing system to perform operations, the operations comprising:
receiving first input data, wherein the first input data comprises first well log data;
fine-tuning a first pre-trained model based upon the first input data to produce a first fine-tuned model;
identifying first low-quality intervals in the first input data having a quality that is below a quality threshold, wherein the first low-quality intervals are identified using the first fine-tuned model, and wherein identifying the first low-quality intervals comprises:
determining a borehole rugosity based upon a first subset of the first input data; and
creating washout flags in the first subset of the first input data based upon the borehole rugosity; and
fine-tuning a second pre-trained model based upon the first low-quality intervals to produce a second fine-tuned model, wherein the second pre-trained model is fine-tuned based upon the washout flags.

12. The computing system of claim 11, wherein a first subset of the first well log data comprises caliper data, wherein a second subset of the first well log data does not include the caliper data, wherein the borehole rugosity is determined based upon the caliper data, and wherein the second pre-trained model is fine-tuned to predict the washout flags in the second subset of the first input data that does not include the caliper data.

13. The computing system of claim 11, further comprising identifying open hole intervals in the first input data, wherein the open hole intervals are identified based upon (1) metadata in the first input data (2) a photo electric factor in the first well log data being above a factor threshold, (3) neutron data in the first well log data being influenced by mud behind a casing, (4) resistivity data in the first well log data presenting anomalous values, and/or (5) acoustic data in the first well log data being influenced by a wave propagating on the casing, wherein the first low-quality intervals are identified in the open hole intervals, wherein the first pre-trained model is fine-tuned based upon the open hole intervals, wherein the first pre-trained model is fine-tuned to classify the borehole in a database, and wherein the first pre-trained model comprises a deep learning model.

14. The computing system of claim 11, wherein identifying the first low-quality intervals further comprises:
predicting coal intervals in the first subset of the first input data that include coal, wherein the coal intervals are predicted using the first pre-trained model; and
deactivating a subset of the washout flags that are aligned with the coal intervals.

15. The computing system of claim 11, wherein the operations further comprise removing the first low-quality intervals from the first input data using the second fine-tuned model to produce filtered data, and wherein the first low-quality intervals are removed from the first subset of the first input data.

16. A non-transitory computer-readable medium storing instructions that, when executed by one or more processors of a computing system, cause the computing system to perform operations, the operations comprising:
receiving first input data, wherein the first input data comprises first well log data, wherein the first well log data comprises measured data and metadata, wherein the measured data is captured by a downhole tool in a borehole, wherein the measured data comprises a photo electric factor, caliper data, resistivity data, acoustic data, neutron data, density data, or a combination thereof, wherein a first subset of the first well log data comprises the caliper data, and wherein a second subset of the first well log data does not include the caliper data;
identifying cased intervals and open hole intervals in the first input data, wherein the cased intervals and the open hole intervals are identified based upon (1) the metadata (2) the photo electric factor being above a factor threshold, (3) the neutron data being influenced by mud behind a casing, (4) the resistivity data presenting anomalous values, and/or (5) the acoustic data being influenced by a wave propagating on the casing;
fine-tuning a first pre-trained model based upon the first input data to produce a first fine-tuned model, wherein the first pre-trained model is fine-tuned based upon the cased intervals and the open hole intervals, wherein the first pre-trained model is fine-tuned to classify the borehole in a database, and wherein the first pre-trained model comprises a deep learning model;
identifying first low-quality intervals in the first input data having a quality that is below a quality threshold, wherein the first low-quality intervals are identified in the open hole intervals, wherein the first low-quality intervals are identified using the first fine-tuned model, wherein the quality is below the quality threshold due to a washout in the borehole and/or missing data, and wherein identifying the first low-quality intervals comprises:
determining a borehole rugosity based upon the first subset of the first input data, wherein the borehole rugosity is determined based upon the caliper data;
creating washout flags in the first subset of the first input data based upon the borehole rugosity;
predicting coal intervals in the first subset of the first input data that include coal, wherein the coal intervals are predicted using the first pre-trained model; and
deactivating a subset of the washout flags that are aligned with the coal intervals;
fine-tuning a second pre-trained model based upon the first low-quality intervals to produce a second fine-tuned model, wherein the second pre-trained model is fine-tuned based upon the washout flags, and wherein the second pre-trained model is fine-tuned to predict the washout flags in the second subset of the first input data that does not include the caliper data;
removing the first low-quality intervals from the first input data using the second fine-tuned model to produce filtered data, wherein the first low-quality intervals are removed from the first subset of the first input data; and
fine-tuning a third pre-trained model based upon the filtered data to produce a third fine-tuned model, wherein the first, second, and/or third pre-trained models are the same pre-trained models or different pre-trained models, wherein the third fine-tuned model comprises a denoising model, wherein the third pre-trained trained model is fine-tuned using denoising multitask paradigms that accounts for missing intervals, depth shifts, intensity shifts, random noises from different distributions, correlated noises, and/or corruption of frequency components.

17. The non-transitory computer-readable medium of claim 16, wherein the operations further comprise:
receiving second input data, wherein the second input data comprises second well log data; and
identifying second low-quality intervals in the second input data having the quality that is below the quality threshold using the third fine-tuned model.

18. The non-transitory computer-readable medium of claim 17, wherein the operations further comprise applying the third fine-tuned model to the second low-quality intervals to produce conditioned data, which improves a completeness and a consistency of the second input data.

19. The non-transitory computer-readable medium of claim 18, wherein the operations further comprise displaying the conditioned data, and wherein the conditioned data is displayed nearby the second input data and the washout flags.

20. The non-transitory computer-readable medium of claim 18, wherein the operations further comprise performing a wellsite action in response to the conditioned data, wherein the wellsite action comprises generating and/or transmitting a signal that recommends, instructs, or causes an action to occur, wherein the action comprises modifying the quality threshold, re-fine-tuning the third fine-tuned model, further modifying the conditioned data, and/or performing a physical action at a wellsite.
